(19) United States
(12) Patent Application Publication
(10) Pub. No.: US 2026/0032358 A1
(43) Pub. Date: Jan. 29, 2026

(54) IMAGE SENSOR

(71) Applicant: SAMSUNG ELECTRONICS CO., LTD., Suwon-si (KR)

(72) Inventors: CHANYOUNG JANG, Suwon-si (KR); YONGSEONG KIM, Suwon-si (KR); YONGHEE YUN, Suwon-si (KR)

(73) Assignee: SAMSUNG ELECTRONICS CO., LTD., Suwon-si (KR)

(21) Appl. No.: 19/244,326

(22) Filed: Jun. 20, 2025

(30) Foreign Application Priority Data
Jul. 23, 2024 (KR) 10-2024-0097535

(51) Int. Cl. H04N 25/704; H10F 39/00

(52) U.S. Cl. CPC H04N 25/704; H10F 39/8053; H10F 39/8063

(57) ABSTRACT

There is provided an image sensor which includes a pixel array and an image processor. The pixel array includes first pixel groups, second pixel groups, and third pixel groups, each of the first pixel groups including first unit pixels and a first color filter, each of the second pixel groups including second unit pixels and a second color filter, and each of the third pixel groups including third unit pixels and a third color filter. The image signal processor performs at least one image processing of the image signals and outputs image-processed image signals. Moreover, the image signal processor changes a target image signal corresponding to a target pixel based on saturation of some of the first unit pixels of a region of interest, and the target pixel is the second unit pixel or the third unit pixel.

### CROSS-REFERENCE TO RELATED APPLICATIONS

This application is based on and claims priority under 35 U.S.C. § 119 to Korean Patent Application No. 10-2024-0097535 filed on Jul. 23, 2024, in the Korean Intellectual Property Office, the disclosures of which are incorporated by reference herein in their entireties.

### BACKGROUND

Embodiments of the disclosure described herein relate to a complementary metal oxide semiconductor (CMOS) image sensor, and more particularly, to an image sensor configured to compensate for a difference between image signals caused due to a disparity of a micro lens.

An image sensor refers to a device which converts a light signal into an electrical signal.

The image sensor includes an autofocus (AF) function to automatically detect a focus when capturing an image. Moreover, a phase difference autofocus (PAF) function makes it possible to adjust a focal length based on a phase difference of light signals detected at different locations.

Recently, image sensors capable of performing the AF function quickly while increasing the resolution is being researched and developed.

### SUMMARY

Embodiments of the disclosure provide an image sensor compensating for a difference between image signals due to a disparity of a micro lens.

According to an aspect of the disclosure, there is provided an image sensor including: a pixel array including first pixel groups, second pixel groups, and third pixel groups arranged in a matrix shape, each of the first pixel groups including a plurality of first unit pixels and a first color filter corresponding to a first color, each of the second pixel groups including a plurality of second unit pixels and a second color filter corresponding to a second color, each of the third pixel groups including a plurality of third unit pixels and a third color filter corresponding to a third color; a readout circuit configured to output image signals based on pixel signals output from the pixel array; and an image signal processor configured to perform one or more image processing operations on the image signals and output image-processed image signals, wherein the image signal processor is further configured to change a target image signal corresponding to a target pixel based on saturation of one or more first first unit pixels among the plurality of first unit pixels in a region of interest, and wherein the target pixel is a second unit pixel, among the plurality of second unit pixels or a third unit pixel, among the plurality of third unit pixels.

According to another aspect of the disclosure, there is provided an image sensor including: a pixel array including first pixel groups, second pixel groups, and third pixel groups are arranged in a matrix shape, each of the first pixel groups including a plurality of first unit pixels and a first color filter corresponding to a first color, each of the second pixel groups including a plurality of second unit pixels and a second color filter corresponding to a second color, each of the third pixel groups including a plurality of third unit pixels and a third color filter corresponding to a third color; a readout circuit configured to output image signals, based on pixel signals output from the pixel array; and an image signal processor configured to: generate first image signals, second image signals, and third image signals by performing white balancing of the image signals, and change at least one of the second image signals and the third image signals based on saturation of one or more first first unit pixels among the plurality of first unit pixels of the first pixel groups and non-saturation of one or more second first unit pixels among the plurality of first unit pixels of the first pixel groups, wherein the first image signals are based on pixel signals of the plurality of first unit pixels of the first pixel groups, the second image signals are based on pixel signals of the plurality of second unit pixels of the second pixel groups, and the third image signals are based on pixel signals of the plurality of third unit pixels of the third pixel groups.

According to an aspect of the disclosure, there is provided an image sensor including: a pixel array including a plurality of pixel groups arranged in a matrix shape; a readout circuit configured to output image signals, based on pixel signals output from the pixel array; and an image signal processor configured to: generate first image signals, second image signals, and third image signals by performing white balancing of the image signals, and output processed image signals obtained by changing at least one of the second image signals and the third image signals based on one or more of the first image signals, the second image signals, and the third image signals reaching a saturation level, wherein the plurality of pixel groups include a first pixel group, a second pixel group, and a third pixel group associated with different color channels, and wherein the first image signals are based on a pixel signal of a first pixel groups, the second image signals are based on a pixel signal of a second pixel groups, and third image signals are based on a pixel signal of a third pixel groups.

### BRIEF DESCRIPTION OF DRAWINGS

The above and other objects and features of the disclosure will become apparent by describing in detail embodiments thereof with reference to the accompanying

### DRAWINGS

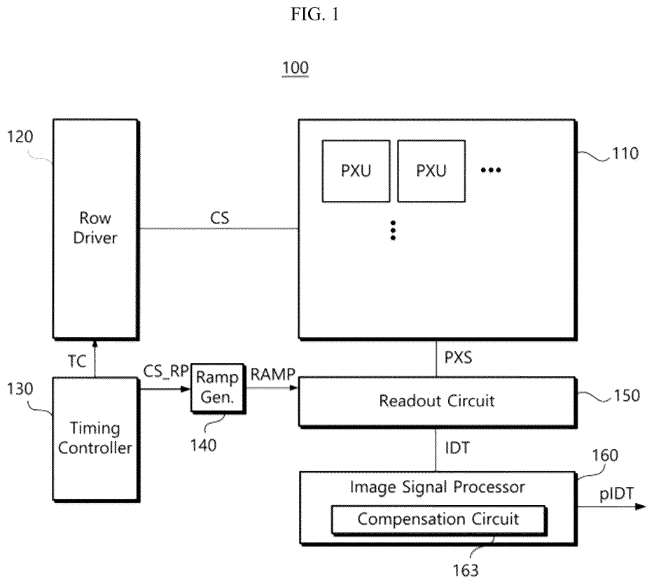

FIG. 1 is a block diagram illustrating an image sensor according to an embodiment of the disclosure.

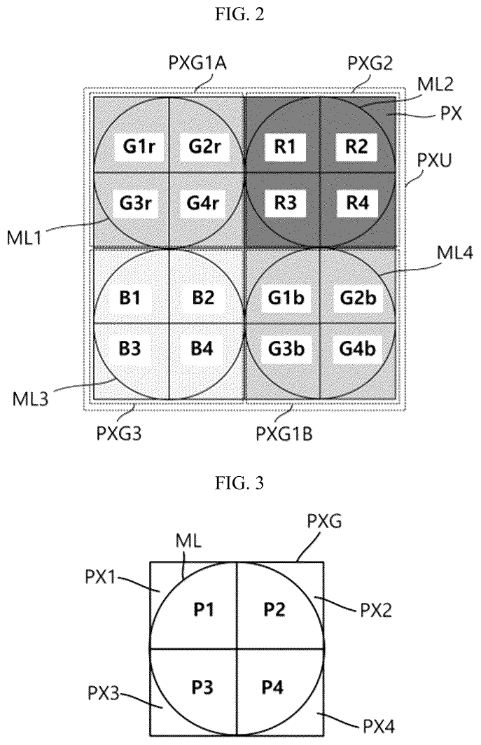

FIG. 2 is a plan view of a pixel unit according to an embodiment of the disclosure.

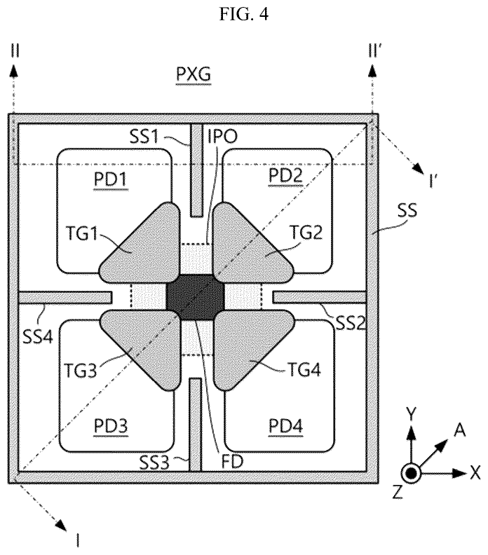

FIG. 3 is a diagram describing phases of unit pixels included in a pixel group according to an embodiment of the disclosure.

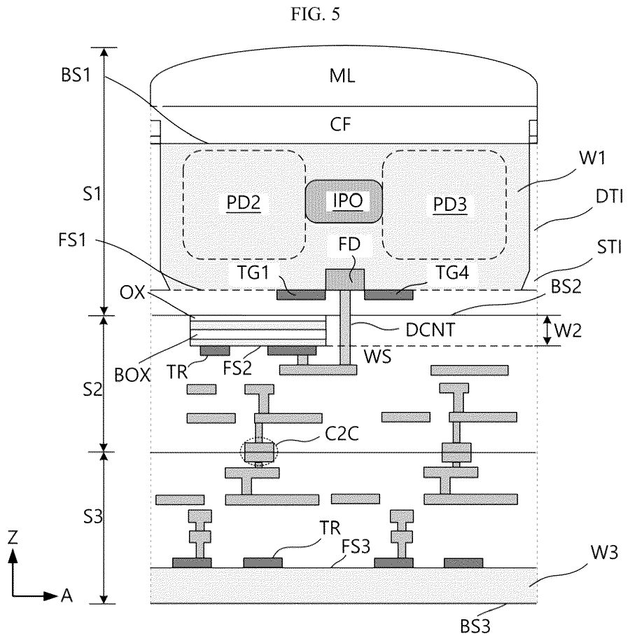

FIG. 4 is a plan view of a pixel group according to an embodiment of the disclosure.

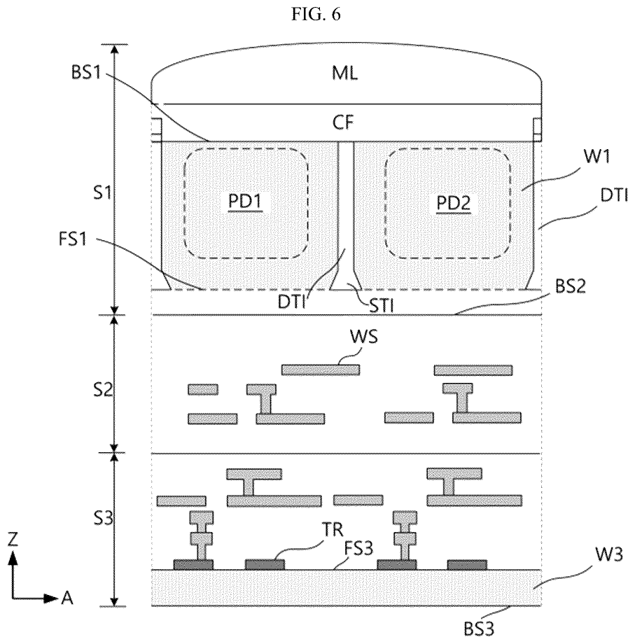

FIG. 5 is a cross-sectional view of a pixel group taken along line I-I′ of FIG. 3, according to an embodiment.

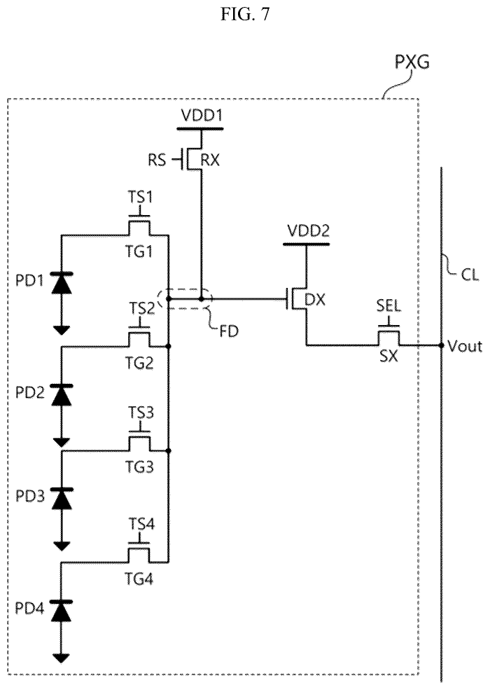

FIG. 6 is a cross-sectional view of a pixel group taken along line II-II′ of FIG. 3, according to an embodiment.

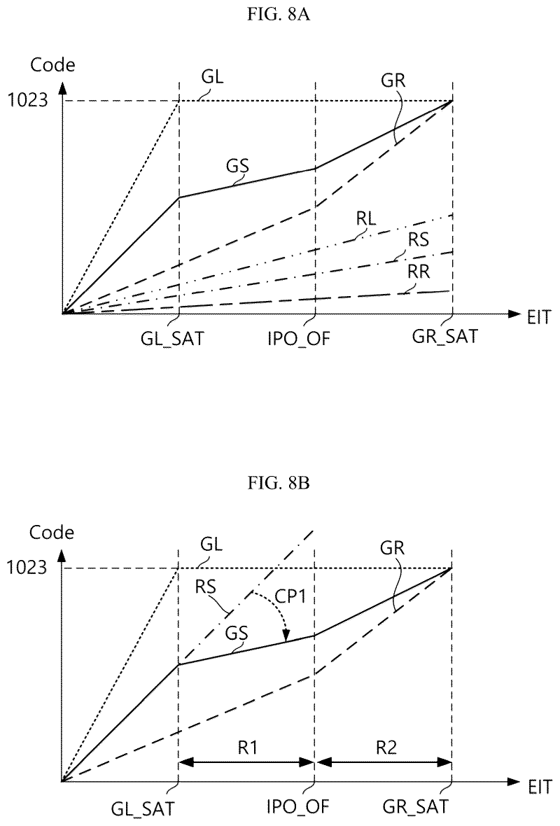

FIG. 7 is a circuit diagram of a pixel group according to an embodiment of the disclosure.

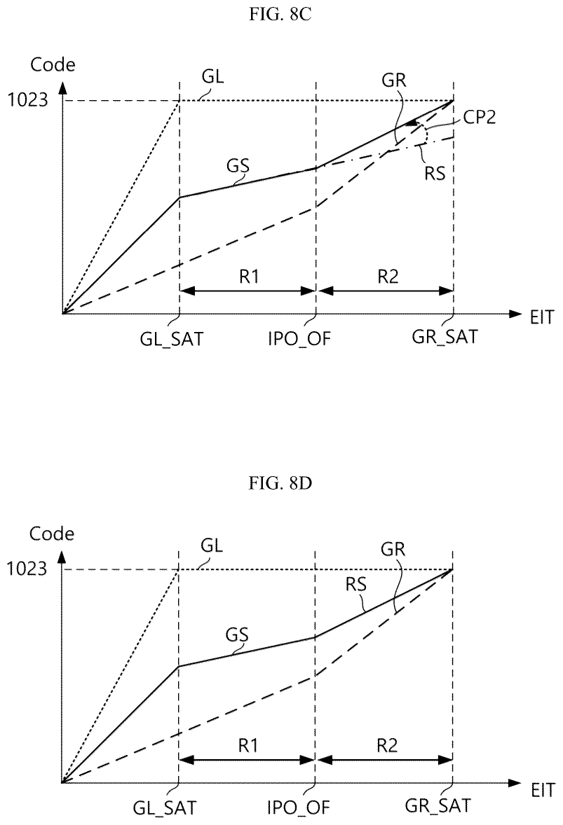

FIGS. 8A to 8D are diagrams schematically describing an image signal compensation process according to an embodiment of the disclosure.

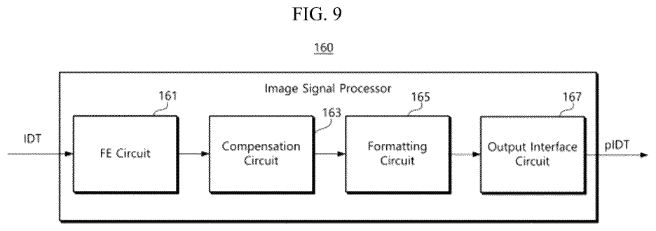

FIG. 9 is a schematic block diagram of an image signal processor according to an embodiment of the disclosure.

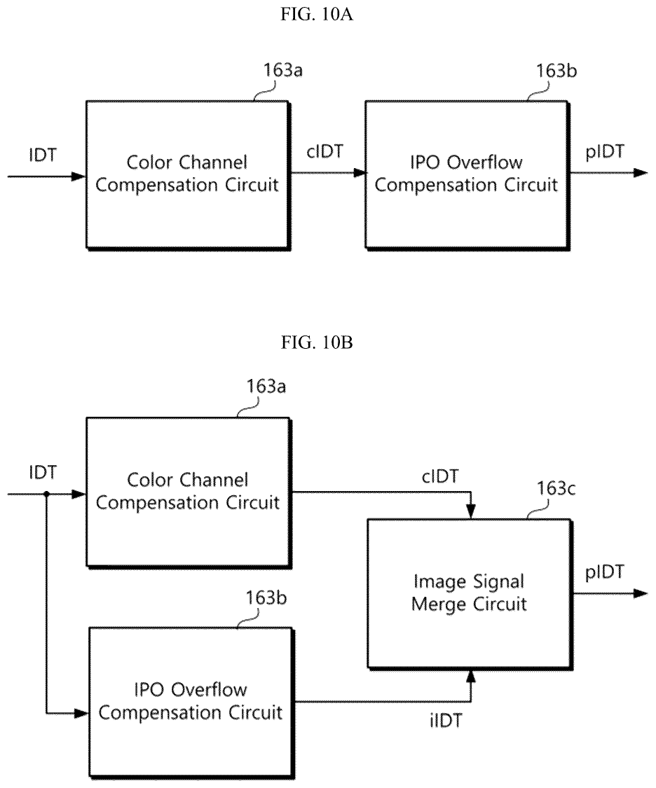

FIGS. 10A and 10B are block diagrams describing a configuration of an image signal processor according to an embodiment of the disclosure.

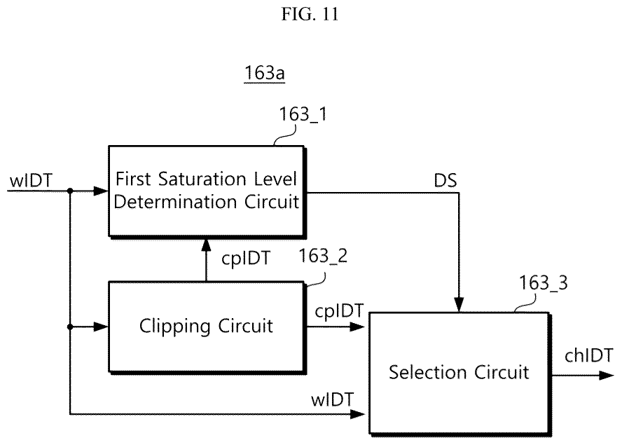

FIG. 11 is a block diagram describing a color channel compensation circuit of an image signal processor according to an embodiment of the disclosure.

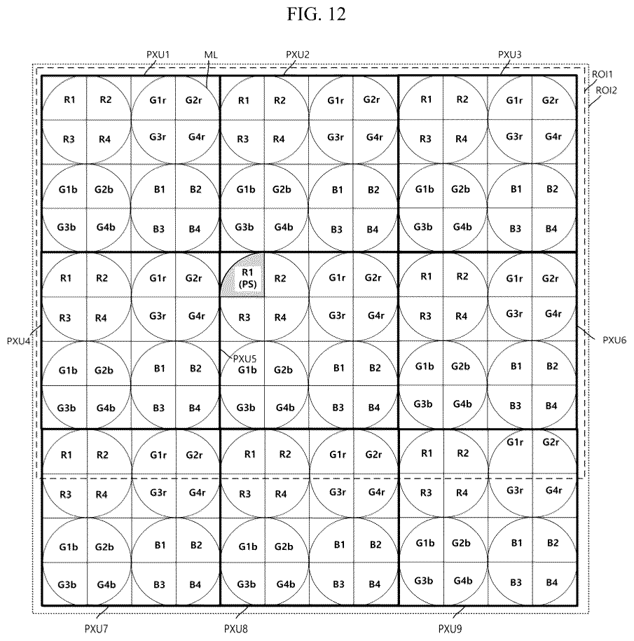

FIG. 12 is a block diagram describing compensation of a color channel difference which a color channel compensation circuit performs, according to an embodiment of the disclosure.

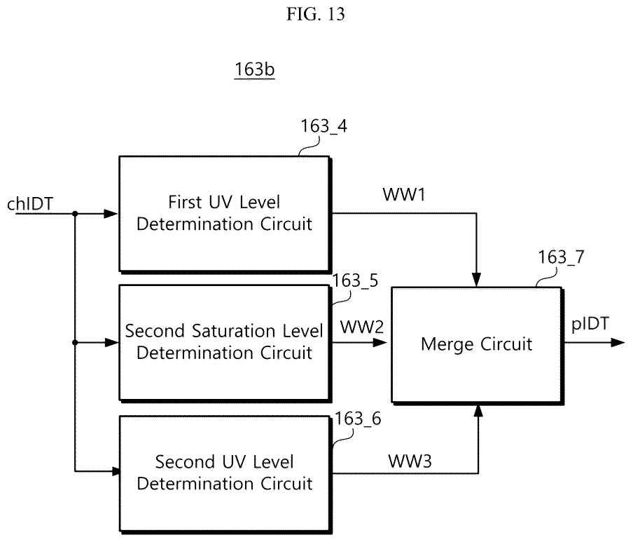

FIG. 13 is a block diagram describing an IPO overflow compensation circuit of an image signal processor according to an embodiment of the disclosure.

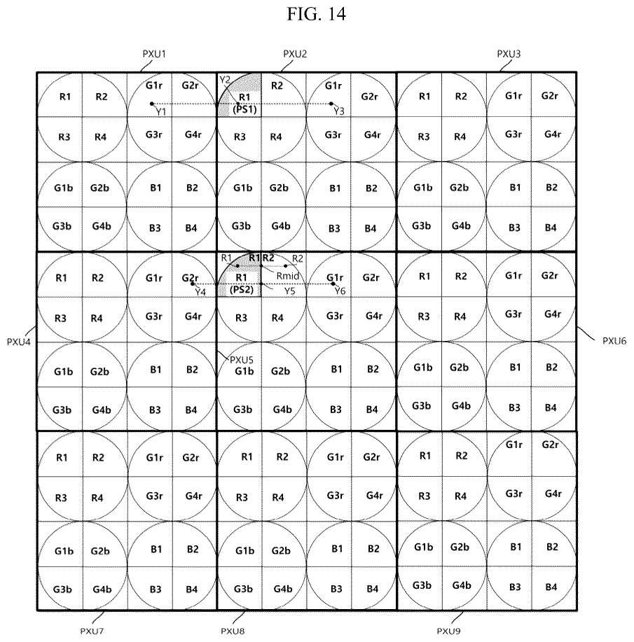

FIGS. 14 to 16 are diagrams describing an operation of an IPO overflow compensation circuit according to an embodiment of the disclosure.

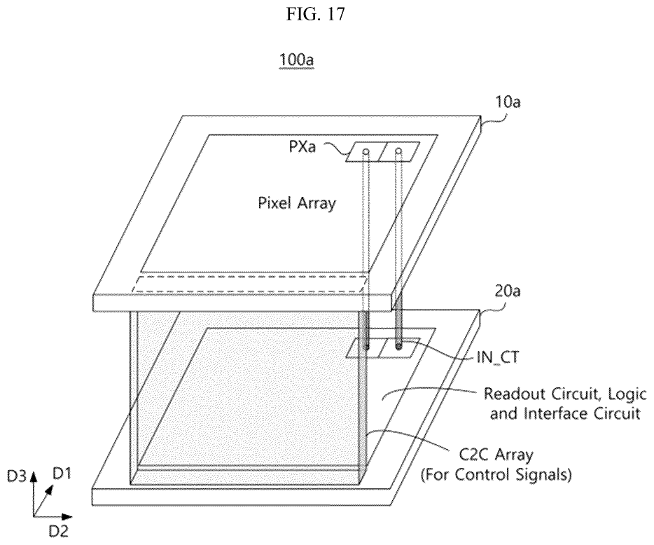

FIG. 17 is a block diagram of an image sensor according to an embodiment of this application.

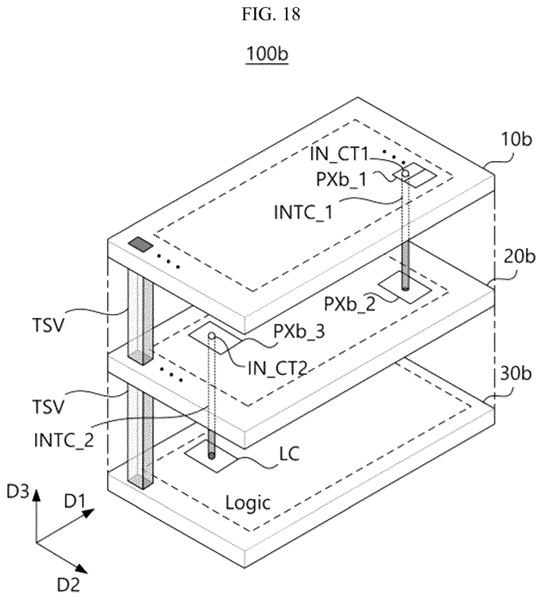

FIG. 18 is a block diagram of an image sensor according to an embodiment of this application.

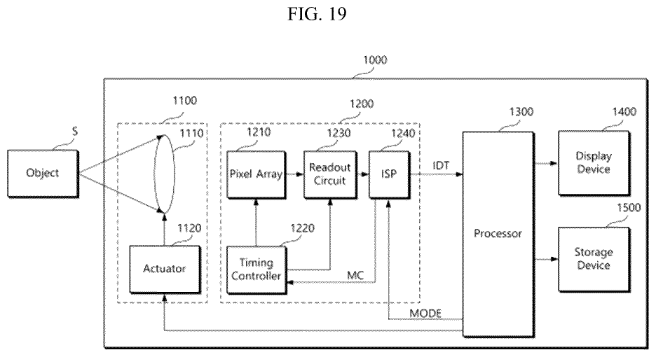

FIG. 19 is a block diagram of an electronic device according to an embodiment of this application.

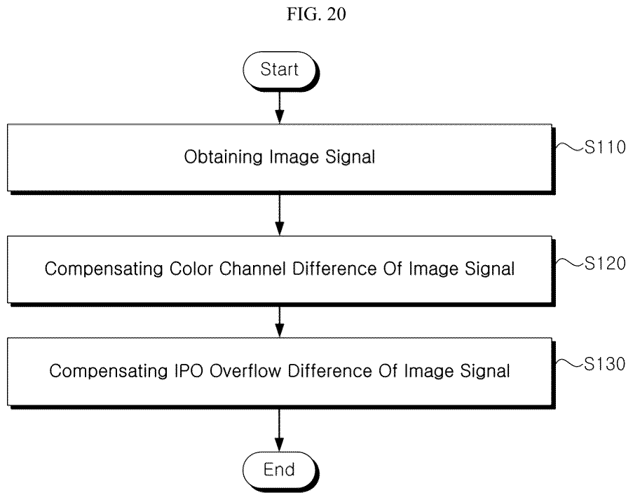

FIG. 20 is a flowchart illustrating an operating method of an image sensor according to an embodiment of this application.

### DETAILED DESCRIPTION

Below, embodiments of the disclosure will be described in detail and clearly to such an extent that an ordinary one in the art easily carries out the disclosure. As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

FIG. 1 is a block diagram illustrating an image sensor 100 according to an embodiment of the disclosure.

According to an embodiment, the image sensor 100 may include an image signal processor 160 configured to compensate for a difference a disparity in a micro lens. For example, the image signal processor 160 may compensate for a difference between image signals caused due to a disparity in the micro lens.

The image sensor 100 according to an embodiment of the disclosure will be described in detail with reference to FIGS. 1 and 2.

In an embodiment, the image sensor 100 may output a pixel signal PXS for each unit pixel. According to another embodiment, the image sensor 100 may output the pixel signal PXS for each pixel group. According to embodiments of the disclosure, the terms “unit pixel” and “pixel” may be interchangeably used.

The image sensor 100 may include a pixel array 110, a row driver 120, a timing controller 130, a ramp signal generator 140, a readout circuit 150, and the image signal processor 160. The image sensor 100 may generate image data representing visual information of an object photographed through a lens. For example, the image signal processor 160 may process an image signal (corresponding to the image data) provided from the readout circuit 150 and may transmit the processed image signal to an external display device and/or an external storage device through an output interface. The readout circuit 150 may include an analog-to-digital converter (ADC) and an output buffer.

The pixel array 110 may include a plurality of pixel units PXUs. The pixel unit PXU may include a plurality of pixel groups PXGs as described with reference to FIG. 2. The pixel group PXG may include a plurality of unit pixels PXs. The pixel group PXG including the plurality of unit pixels PXs will be described in detail with reference to FIG. 2. In FIG. 1, the description of the image sensor 100 is based the pixel unit PXU including the plurality of pixel groups PXGs as illustrated in FIG. 2 or the pixel unit PXU including a plurality of pixels PXs as illustrated in FIG. 3. However, the disclosure is not limited thereto.

The pixel array 110 may receive a plurality of pixel driving signals CS from the row driver 120. The plurality of pixel driving signals CS may include, but is not limited to, a selection signal controlling a select transistor, a reset signal controlling a reset transistor, and a transfer transistor control signal controlling a transfer transistor. Each of the plurality of pixel units PXUs of the pixel array 110 operates under control of the pixel driving signals CS received from the row driver 120. Each of the plurality of unit pixels PXs included in each of the pixel units PXUs operates under control of the pixel driving signals CS received from the row driver 120.

The plurality of pixel units PXUs may be arranged, for example, in the shape of a matrix. Each of the pixel groups PXGs included in the pixel units PXUs and/or each of the pixels PXs included in the pixel units PXUs may be connected to a row line and a column line.

In an embodiment, each pixel group PXG may be based on a multi-pixel structure including a plurality of photodiodes. In the pixel group PXG based on the multi-pixel structure, the plurality of unit pixels PXs may share at least some of pixel circuits.

For example, each pixel group PXG may include a plurality of transistors which are controlled by the row driver 120. The unit pixels PXs included in the same pixel group PXG may share at least some of a drive transistor, a select transistor, and a reset transistor.

The row driver 120 may select one row or a plurality of rows of the pixel array 110 under control of the timing controller 130. According to embodiments of the disclosure, the “row” means the plurality of unit pixels PXs provided in a first direction (e.g., a horizontal direction) from among the plurality of unit pixels PXs. Also, the “column” means the plurality of unit pixels PXs provided in a second direction (e.g., a vertical direction) from among the plurality of unit pixels PXs included in the pixel array 110.

The row driver 120 may drive at least one row among the plurality of rows. The row driver 120 may generate a selection signal to drive at least one row among the plurality of rows. The row driver 120 may activate unit pixels PXs and/or pixel groups PXGs corresponding to the selected row. The pixel signals PXS of the unit pixels PXs and/or the pixel groups PXGs belonging to the selected row may be transmitted to the readout circuit 150 through a plurality of column output lines.

According to an embodiment, the pixel signal PXS may correspond to a voltage of a floating diffusion region. The pixel signal PXS may correspond to a voltage to which charges generated by photodiodes PD included in the plurality of unit pixels PXs are applied. According to another embodiment, the pixel signal PXS may correspond to a reference voltage which is used to perform correlated double sampling (CDS) with a voltage to which charges generated by the photodiodes PD are applied. The reference voltage may be the voltage of the floating diffusion region. For example, the reference voltage may be the voltage of the floating diffusion region reset by a reset voltage.

The timing controller 130 may control the pixel array 110, the row driver 120, the ramp signal generator 140, and the readout circuit 150. The timing controller 130 may provide a timing control signal TC to the row driver 120.

In an embodiment, the timing control signal TC may be differently set based on an operation mode of the image sensor 100. For example, the image sensor 100 may operate in a signal output mode for each unit pixel PX included in the pixel group PXG or in a signal output mode for each pixel group PXG included in the pixel unit PXU. For example, the signal output mode for each pixel group PXG may refer to a binning mode in which pixel signals of unit pixels PXs included in the same pixel group PXG are merged and output.

The operation mode of the image sensor 100 may be selected based on a input from the user. However, the disclosure is not limited thereto, and as such, according to another embodiment, the operation mode of the image sensor 100 may be set under control of an external processor or under control of the image signal processor 160.

The row driver 120 may drive each of the plurality of pixels PXs in a normal photographing mode or an HDR mode, based on the timing control signal TC.

In an embodiment, in an example case in which the image sensor 100 operates in the HDR mode which is based on an exposure time, the row driver 120 may drive the plurality of pixels PXs respectively such that at least two kinds of pixel signals PXS are generated, each of the at least two kinds of pixel signals PXS having different exposure times. For example, the row driver 120 may control the plurality of pixels PXs respectively such that a second pixel signal corresponding to a second exposure time is generated after a first pixel signal corresponding to a first exposure time is generated. The first exposure time may be different from the second exposure time. The first exposure time may be longer or shorter than the second exposure time.

The timing controller 130 may control the ramp signal generator 140 through a ramp control signal CS_RP. The ramp control signal CS_RP may include a ramp enable signal, a mode signal, etc.

The ramp signal generator 140 may generate a ramp signal RAMP in response to the ramp control signal CS_RP. The ramp signal generator 140 may generate the ramp signal RAMP with a preset slope. The ramp signal generator 140 may provide the generated ramp signal RAMP to the ADC of the readout circuit 150.

The ADC of the readout circuit 150 may output image signals IDTs being a digital signal, based on pixel signals which are based on the ramp signal RAMP. For example, the ADC may output the pixel signals PXS as the image signals IDTs based on the ramp signal RAMP, in the correlated double sampling method. The image signals IDTs may be provided to the image signal processor 160. The image signals IDTs may have intensity values corresponding to the pixel signals PXS.

The image signal processor 160 according to an embodiment of this application may compensate for a difference due to the disparity in the micro lens, in association with the image signals IDTs which the readout circuit 150 outputs. According to another embodiment, the image signal processor 160 may compensate for a difference between an image signal IDT of one color channel and an image signal IDT of another color channel, due to the disparity in the micro lens. According to another embodiment, the image signal processor 160 may compensate for a difference between the image signals IDTs of the pixels PXs placed on one side of the pixel group PXG and the image signals IDTs of the pixels PXs placed on an opposite side of the pixel group PXG, due to the disparity in the micro lens.

The image signal processor 160 may change at least some of the image signals IDTs not saturated, in response to that at least some of the image signals IDTs reach a saturation level.

For example, the image signal processor 160 may determine the saturation of the unit pixels PXs placed on one side of the pixel group PXG corresponding to one color channel from among the unit pixels PXs. In this case, the image signal processor 160 may change at least some of the image signals IDTs of the pixel group PXG corresponding to another color channel. According to an embodiment, additionally or selectively, there may be determined whether some of the image signals IDTs of the pixel group PXG corresponding to the another color channel reach the saturation level.

FIG. 2 is a plan view of the pixel unit PXU according to an embodiment of the disclosure. The pixel unit PXU according to the embodiment illustrated FIG. 2 may correspond to the pixel unit PXU of FIG. 1. As described with reference to FIG. 1, the pixel units PXU according to the embodiment of FIG. 2 may be placed in the pixel array 110 of the image sensor 100 in the shape of a matrix.

The pixel unit PXU according to an embodiment of the disclosure may include the plurality of pixel groups PXGs. The number of pixel groups PXGs included in the pixel unit PXU may depend on a color filter pattern. In an example case in which the image sensor 100 has the Bayer color pattern, four pixel groups PXGs may be included in the pixel unit PXU. However, the disclosure is not limited thereto, and as such, according to an embodiment, the pixel unit PXU may depend on another color pattern different from the Bayer color pattern.

In an embodiment, color filters placed in adjacent pixel groups PXGs among the plurality of pixel groups PXGs may transmit lights of different spectra. For example, colors of color filters of adjacent pixel groups PXGs may be different from each other.

According to an embodiment, some pixel groups PXGs, among the pixel groups PXGs of the pixel unit PXU may correspond to a color pattern of different colors, and some other pixel groups PXGs, among the pixel groups PXGs of the pixel unit PXU may correspond to a color pattern of the same color. In an example case in which the pixel unit PXU includes four pixel groups PXGs, two first pixel groups may correspond to a first color channel, a second pixel group may correspond to a second color channel, and a third pixel group may correspond to a third color channel. According to an embodiment, Different color filters may be provided for respective color channels.

Referring to FIG. 2, in an example case in which the pixel unit PXU are based on the Bayer color pattern, the first color channel may be a green color channel, the second color channel may be a red color channel, and a third color channel may be a blue color channel. According to embodiments of the disclosure, it is assumed that different color filters are provided in the pixel groups PXGs distinguished based on a pattern of different hatchings or dots.

The pixel group PXG may include the plurality of unit pixels PXs. The unit pixels PXs included in the pixel group PXG may be arranged in the shape of an N×N matrix in which the same number of pixels, denoted as “N”, are placed in the horizontal direction and the vertical direction. For example, the pixel group PXG may include the unit pixels PXs provided in the shape of a 2×2 matrix or may include the unit pixels PXs provided in the shape of a 3×3 matrix. The description related to the illustration in FIG. 2 will be given under the condition that the pixel group PXG includes the unit pixels PXs provided in the shape of a 2×2 matrix, but in other embodiments, the pixel group PXG may be implemented to be different from the above matrix shape.

The unit pixels PXs of the same pixel group PXG may share one micro lens. For example, referring to FIG. 2, unit pixels G1r, G2r, G3r, and G4r of a first pixel group PXG1A may share a first micro lens ML1, unit pixels G1b, G2b, G3b, and G4b of a first pixel group PXG1B different from the first pixel group PXG1A may share a fourth micro lens ML4, unit pixels R1, R2, R3, and R4 of a second pixel group PXG2 may shape a second micro lens ML2, and unit pixels B1, B2, B3, and B4 of a third pixel group PXG3 may share a third micro lens ML3.

Each of the unit pixels PXs may include a photoelectric conversion element which converts a light signal incident thereon into an electrical signal. Each of the pixels PXs may include at least one photoelectric conversion element. Each of the unit pixels PXs of the same pixel group PXG may generate photoelectrons in response to the light passing through a color filter corresponding to the same color channel.

The photoelectric conversion element may be a photodiode (PD). The photoelectric conversion element may include, but is not limited to, one of a photodiode (PD), a photocapacitor, a photogate, a pinned photodiode (PPD), a partially pinned photodiode, an organic photo diode (OPD), and a quantum do (QD), or a combination thereof. According to embodiments of disclosure, the photoelectric conversion element is the photodiode (PD). However, the disclosure is not limited thereto, and as such, the above photoelectric conversion elements may be used as the photoelectric element, and the photoelectric conversion element is not limited to the photodiode (PD).

FIG. 3 is a diagram describing phases of unit pixels PX1, PX2, PX3, and PX4 included in the pixel group PXG according to an embodiment of the disclosure. The pixel group PXG of FIG. 3 may correspond to each of the pixel groups PXG1A, PXG1B, PXG2, and PXG3 of FIG. 2.

Referring to FIG. 3, the unit pixels PX1, PX2, PX3, and PX4 of the pixel group PXG according to embodiment of the disclosure share one micro lens ML. The light signal passing through the same micro lens ML is incident on each of the unit pixels PX1, PX2, PX3, and PX4 through the color filter.

Light paths of the light signals respectively incident on the unit pixels PX1, PX2, PX3, and PX4 may be different from each other depending on the refraction of the micro lens ML. The light signals respectively incident on the unit pixels PX1, PX2, PX3, and PX4 may have phases P1, P2, P3, and P4. Depending on photographing environments, such as a location and a focus of a target to be photographed, a length of a light path of a light signal incident on one unit pixel among the unit pixels PX1, PX2, PX3, and PX4 may be different from a length of a light path of a light signal incident on another unit pixel among the unit pixels PX1, PX2, PX3, and PX4.

For example, in any photographing environment, image signals of the unit pixels PX1 and PX3 placed on a first side of the pixel group PXG may be different in magnitude from image signals of the unit pixels PX2 and PX4 placed on a second side of the pixel group PXG due to a difference between the light paths. For example, the first side of the pixel group PXG may be the left side of the pixel group PXG and the second side of the pixel group PXG may be the right side of the pixel group PXG. However, the disclosure is not limited thereto. According to embodiments of the disclosure, the first side of the pixel group PXG may mean a location close to any one boundary of the pixel group PXG. Accordingly, the first side of the pixel group PXG may be one of a left side, a right side, an upper side, and a lower side. Below, embodiments will be described based on the left side and the right side of the pixel group PXG, but the technical idea of the disclosure is not limited thereto.

According to embodiments of the disclosure, in different pixel groups, unit pixels provided at the same location relative to the micro lens ML receive light signals of the same phase through the micro lenses ML. For example, in different pixel groups, unit pixels provided at the location of the first unit pixel PX1 relative to the micro lens ML may receive light signals of the same phase through the micro lenses ML.

FIG. 4 is a plan view of a pixel group according to an embodiment of the disclosure The pixel group PXG according to the embodiment of FIG. 4 may correspond to one of the first pixel groups PXG1A and PXG1B of FIG. 2. The embodiment of FIG. 4 will be described based on the first pixel groups PXG1A and PXG1B of FIG. 2, but as will be described below, the remaining components other than an overflow region IPO may also be identically applied to the second pixel group PXG2 and the third pixel group PXG3 of FIG. 2.

The pixel group PXG may be divided by a device isolation structure SS. The pixel group PXG may include 4-shared unit pixels including four photodiodes PD1, PD2, PD3, and PD4 formed in a substrate. Each of the first to fourth photodiodes PD1, PD2, PD3, and PD4 may form a separate unit pixel. As described with reference to FIG. 2, according to an embodiment, the number of photodiodes included in the pixel group PXG may be different from that illustrated in FIG. 3.

The unit pixels in the same pixel group PXG may share at least some of pixel circuits. Referring to FIG. 4, the first to fourth photodiodes PD1, PD2, PD3, and PD4 share the same floating diffusion region FD. For example, the first to fourth photodiodes PD1, PD2, PD3, and PD4 share one floating diffusion region FD. The first to fourth photodiodes PD1, PD2, PD3, and PD4 may be provided along a radiation direction, with the floating diffusion region FD centered. For example, the first to fourth photodiodes PD1, PD2, PD3, and PD4 may be provided in the pixel group PXG so as to surround the floating diffusion region FD.

The first to fourth photodiodes PD1, PD2, PD3, and PD4 may transfer charges to the floating diffusion region FD through first to fourth transfer gates TG1, TG2, TG3, and TG4 respectively corresponding thereto.

The unit pixels including the first to fourth photodiodes PD1, PD2, PD3, and PD4 respectively may share a drive transistor, a select transistor, and a reset transistor, but the disclosure is not limited thereto.

In an embodiment, referring to FIG. 4, the unit pixels including the first to fourth photodiodes PD1, PD2, PD3, and PD4 respectively may be separated from each other by first to fourth device isolation structures SS1, SS2, SS3, and SS4. However, the disclosure is not limited thereto, and as such, according to another embodiment, the pixel group PXG may not include the first to fourth device isolation structures SS1, SS2, SS3, and SS4.

One pixel group PXG among pixel groups according to an embodiment of the disclosure may include the overflow region IPO which provides a transfer path of overflowed charges between unit pixels, and the remaining pixel groups among pixel groups may not include the overflow region IPO. The overflow region IPO may be in contact with each of the first to fourth photodiodes PD1, PD2, PD3, and PD4.

For example, each of the first pixel groups PXG1A and PXG1B of FIG. 2 may include the overflow region IPO. The second pixel group PXG2 and the third pixel group PXG3 may not include the overflow region IPO. In an example case in which pixel groups are based on the Bayer color pattern, each of the pixel groups PXGs corresponding to the green color channel may include the overflow region IPO.

Overflowed charges which are generated when the amount of charges generated by at least one of the first to fourth photodiodes PD1, PD2, PD3, and PD4 exceeds a full well capacity (FWC) may move to the remaining photodiodes through the overflow region IPO. Accordingly, the FWC of the pixel group PXG may be increased by the overflow region IPO.

FIG. 5 is a cross-sectional view of the pixel group PXG taken along line I-I′ of FIG. 4, according to an embodiment. The cross-sectional view according to the embodiment of FIG. 4 may correspond to one of the first pixel groups PXG1A and PXG1B of FIG. 2. The embodiment of FIG. 5 will be described based on the first pixel groups PXG1A and PXG1B of FIG. 2, but as will be described below, the remaining components other than the overflow region IPO may also be identically applied to the second pixel group PXG2 and the third pixel group PXG3 of FIG. 2.

Referring to FIG. 5, the pixel group PXG may include a first structure S1, a second structure S2, and a third structure S3.

In an embodiment, the first structure S1 may include the photodiode PD, the transfer gates TG1 and TG4, and the floating diffusion region FD.

In an embodiment, pixel circuits of the pixel group PXG may be placed in the second structure S2. According to another embodiment, some pixel circuits among the pixel circuits of the pixel group PXG may be placed in the first structure S1, and the some other pixel circuits among the pixel circuits of the pixel group PXG may be placed in the second structure S2. For example, in an embodiment, FIG. 5 shows that the floating diffusion region FD of the first structure S1 is directly connected to a transistor TR of the second structure S2. However, unlike the example of FIG. 5, the floating diffusion region FD of the first structure S1 may be electrically connected to the transistor TR of the second structure S2 through any other pixel circuit of the first structure S1.

In an embodiment, the third structure S3 may include a readout circuit, a timing controller, logic such as an image signal processor, and an interface circuit.

In an embodiment, the first structure S1, the second structure S2, and the third structure S3 may include a wiring layer WS for transferring an electrical signal.

In an embodiment, the first structure S1 may include a first surface FS1 and a second surface BS1 opposite to each other (or facing away from each other). The first surface FS1 may be a front surface of the first surface FS1, and the second surface BS1 may be a back surface of the first structure S1. For example, an image sensor may be a backside illumination type (BSI) image sensor in which a light is incident on the back surface of the first structure S1.

In an embodiment, the pixel group PXG placed in the first structure S1 may include the plurality of photodiodes PD, a color filter CF, and the micro lens ML.

In an embodiment, a plurality of deep trench isolation DTI which extend from the second surface BS1 toward the first surface FS1 may be formed between the first surface FS1 and the second surface BS1 of the first structure S1. For example, the plurality of deep trench isolation DTI may be formed between the first surface FS1 and the second surface BS1 of a first substrate W1. The pixel groups PXGs may be distinguished from each other by the deep trench isolation DTI.

In an embodiment, the first structure S1 may include a shallow trench isolation STI.

In an embodiment, the shallow trench isolation STI may extend from the first surface FS1 of the first substrate W1 toward the second surface BS1 of the first substrate W1 as much as a given depth and may include an insulating material. In this case, the shallow trench isolation STI may be connected to the deep trench isolation DTI, and the boundary between the shallow trench isolation STI and the deep trench isolation DTI may be unclear.

In an embodiment, the shallow trench isolation STI may be formed as a doping region with a given depth from the first surface FS1 of the first substrate W1 toward the second surface BS1 of the first substrate W1. The doping region may be doped with a P-type material.

In an embodiment, the second structure S2 may include a second substrate W2.

In an embodiment, the second substrate W2 may be a silicon-on-insulator (SOI) substrate. In this case, after the SOI substrate is bonded to the first structure S1, a portion of the SOI substrate may be ground, polished, or ion-cut so as to be separated therefrom. In this case, the second structure S2 may include an oxide layer OX and a buried oxide (BOX) layer. The second substrate W2 may be called an active layer.

In an embodiment, unlike the embodiment illustrated in FIG. 5, the second substrate W2 may not include the buried oxide (BOX) layer. For example, the second substrate W2 may be a typical semiconductor substrate, not the SOI substrate.

In an embodiment, the first structure S1 and the second structure S2 may be electrically connected to each other through a deep-contact structure DCNT. The deep-contact structure DCNT may be formed of a contact crossing at least a portion of the first structure S1 and at least a portion of the second structure S2. The deep-contact structure DCNT may be formed after the first structure S1 and the second structure S2 are bonded. In an embodiment, the deep-contact structure DCNT may include an electrical connection path formed of tungsten.

According to another embodiment, unlike the embodiment illustrated in FIG. 5, the first structure S1 and the second structure S2 may be electrically connected to each other through a through silicon via (TSV).

According to another embodiment, the first structure S1 and the second structure S2 may be electrically connected to each other through a Cu-to-Cu (C2C) bonding contact.

According to another embodiment, the first structure S1 and the second structure S2 may be electrically connected to each other through all of the Cu-to-Cu (C2C) bonding contact, the deep-contact structure DCNT, and the through silicon via.

In an embodiment, the second structure S2 and the third structure S3 may be electrically connected through the Cu-to-Cu (C2C) bonding contact. According to another embodiment, the second structure S2 and the third structure S3 may be electrically connected to each other through the through silicon via (TSV) and/or a TSC.

In an embodiment, the first surface FS1 of the first substrate W1 may face a third surface BS2 of the second substrate W2, and a fourth surface FS2 of the second substrate W2 may face a fifth surface FS3 of a third substrate W3.

The overflow region IPO of the pixel group PXG according to an embodiment of the disclosure may be placed in the first structure S1. The overflow region IPO may be placed to be spaced away from the first surface FS1 of the first structure S1 as much as a given depth.

In an embodiment, the overflow region IPO may be formed with a doped semiconductor region having conductivity type that is identical to the conductivity type of each of the photodiodes PD1 and PD4. For example, the overflow region IPO may be formed with a semiconductor region doped with N-type impurities. In an embodiment, the impurity doping concentration of the photodiodes PD1 and PD4 may be substantially identical or similar to the impurity doping concentration of the overflow region IPO. According to another embodiment, the impurity doping concentration of the photodiodes PD1 and PD4 may be higher than the impurity doping concentration of the overflow region IPO.

As described with reference to FIG. 4, some pixel groups belonging to the same pixel unit may not include the overflow region IPO.

FIG. 6 is a cross-sectional view of the pixel group PXG taken along line II-II′ of FIG. 4, according to an embodiment. The description which is the same as the description given based on the embodiment of FIG. 5 will be omitted to avoid redundancy.

Referring to FIG. 6, a pixel group may include the shallow trench isolation STI and the deep trench isolation DTI between the first photodiode PD1 and the second photo diode PD2. The shallow trench isolation STI and the deep trench isolation DTI of FIG. 6 may correspond to the first to fourth device isolation structures SS1, SS2, SS3, and SS4 of FIG. 3.

FIG. 7 is a circuit diagram of the pixel group PXG according to an embodiment of the disclosure. The pixel group PXG of FIG. 7 may correspond to each of the pixel groups of FIGS. 2 and 4.

Referring to FIG. 7, the pixel group PXG according to an embodiment of the disclosure may include the first to fourth photodiodes PD1, PD2, PD3, and PD4, the first to fourth transfer gates TG1, TG2, TG3, and TG4, the floating diffusion region FD, a reset transistor RX, a drive transistor DX, and a select transistor SX. Each of the first to fourth transfer gates TG1, TG2, TG3, and TG4, the reset transistor RX, the drive transistor DX, and the select transistor SX may be controlled by the row driver 120 of FIG. 1.

The first to fourth photodiodes PD1, PD2, PD3, and PD4 may transfer charges to the floating diffusion region FD through the first to fourth transfer gates TG1, TG2, TG3, and TG4 respectively corresponding thereto.

The reset transistor RX may connect a first pixel power supply voltage VDD1 and the floating diffusion region FD and may be controlled by a reset control signal RS.

The drive transistor DX may be a source follower transistor and may be controlled by a voltage of the floating diffusion region FD. The drive transistor DX may provide one terminal of the select transistor SX with an output signal obtained by amplifying a voltage provided to a gate terminal of the drive transistor DX.

The select transistor SX may output a pixel signal Vout provided from the drive transistor DX to a column line CL based on control of a selection signal SEL.

The unit pixels included in the same pixel group PXG according to an embodiment of the disclosure may share the drive transistor DX, the select transistor SX, and the reset transistor RX.

FIGS. 8A to 8D are diagrams schematically describing a process in which an image signal processor compensates for an image signal, according to an embodiment of the disclosure. The compensation of the image signal may be performed by the image signal processor 160 of FIG. 1. According to an embodiment, the manner in which the image signal processor 160 compensates for the image signal will be described with reference to FIGS. 1, 2, 3, and 8A to 8D.

FIG. 8A illustrates change in the image signals of the pixel unit PXU of FIG. 2 based on an exposure time EIT. In FIG. 8A, a code (vertical axis) may mean a magnitude of a digitalized image signal. FIG. 8A shows the change in image signals not experiencing the compensation by the image signal processor 160. FIGS. 8A and 8D will be described under the condition that a pixel signal is converted into a 10-bit image signal by the readout circuit 150 of FIG. 1. The maximum value of the code may differ depending on the configuration of the readout circuit 150.

FIG. 8A shows first image signals GL and GR based on pixel signals of the first pixel groups PXG1A and PXG1B of FIG. 2 and second image signals RL and RR based on pixel signals of the second pixel group PXG2 of FIG. 2. Even though third image signals based on pixel signals of the third pixel group PXG3 of FIG. 2 are not illustrated in FIGS. 8A to 8D, the third image signals may be similar to the second image signals RL and RR.

A first image signal average code GS may be an average code of the image signals GL of unit pixels placed on a left side of each of the first pixel groups PXG1A and PXG1B and the image signals GR of unit pixels placed on a right side of each of the first pixel groups PXG1A and PXG1B. Likewise, a second image signal average code RS may be an average code of the image signals RL of unit pixels placed on a left side of the second pixel group PXG2 and the image signals RR of unit pixels placed on a right side of the second pixel group PXG2. For convenience of description, regarding the second image signals, only the second image signal average code RS is illustrated in FIGS. 8B to 8D.

Referring to FIG. 8A, the linearity of the first image signal average code GS, which is an average code of the first image signals GL and GR, may vary depending on an exposure time, for each time period. The linearity may mean a statistically linear characteristic, and may not be a certainly complete straight line. The first image signals GL and GR may be based on pixel signals of unit pixels corresponding to the green color channel.

For example, referring to FIG. 8A, the first image signal average code GS may increase with a first increasing rate until the first image signal arrives at a first exposure time GL_SAT when the unit pixels placed on the left side of the first pixel groups PXG1A and PXG1B are saturated. As described with reference to FIG. 2, unit pixels of a pixel group share the same micro lens. Accordingly, depending on a photographing environment, due to a difference between light paths due to the disparity in the micro lens, unit pixels placed on one side of the pixel group may be saturated prior to unit pixels placed on another side of the pixel group. For example, in a case in which the pixel group is based on the Bayer pattern, unit pixels placed on one side of a pixel group corresponding to the green color channel may be saturated prior to unit pixels placed on another side of the pixel group. According to embodiments of disclosure, unit pixels placed on the left side of the pixel group corresponding to the green color channel may be saturated prior to unit pixels placed on the right side of the pixel group. However, this is provided for convenience of description, and the technical idea of the disclosure is not limited thereto. For example, depending on a photographing environment, the unit pixels placed on the right side of the pixel group corresponding to the green color channel may be saturated prior to the unit pixels placed on the left side of the pixel group.

As shown in FIG. 8A, the first image signal average code GS may increase with a second increasing rate from the first exposure time GL_SAT to a second exposure time IPO_OF. The second exposure time IPO_OF may be a point in time when charges overflowed from the unit pixels placed on the left side of the first pixel groups PXG1A and PXG1B start to move to the unit pixels placed on the right side by the overflow region IPO of FIGS. 4 and 5. The first image signal average code GS may increase with a third increasing rate from the second exposure time IPO_OF to a third exposure time GR_SAT. The third exposure time GR_SAT may be a point in time when the unit pixels placed on the right side of the first pixel groups PXG1A and PXG1B are also saturated. At least some of the first increasing rate, the second increasing rate, and the third increasing rate may be different from each other.

Unlike the above description, the image signals of the second pixel group PXG2 and the third pixel group PXG3 of FIG. 2 may have the same linearity depending on an exposure time. The second image signals RL and RR may be based on pixel signals of unit pixels corresponding to the red color channel. According to an embodiment, the third image signals may be based on pixel signals of unit pixels corresponding to the blue color channel.

For example, referring to FIG. 8A, the second image signals RL and RR may increase with substantially the same increasing rate until the second image signals RL and RR pass the first exposure time GL_SAT and the second exposure time IPO_OF and then arrives at the third exposure time GR_SAT. Accordingly, the second image signal average code RS may also increase with the same increasing rate depending on the change in the exposure time EIT. The third image signals may also be similar to the second image signals RL and RR.

FIG. 8B shows image signals of FIG. 8A experiencing the white balancing by the image signal processor 160.

For example, referring to FIG. 8A, the image signal processor 160 may multiply a weight and the second image signals RL and RR together. The weight may be a preset weight constant. The white balancing method may vary depending on an embodiment. According to embodiments of disclosure, the white balancing is performed by using a method of multiplying a weight constant and the second image signals together and multiplying a weight constant and the third image signals together. However, the technical idea of the disclosure is not limited thereto.

Referring to FIG. 8B, in an embodiment, the image signal processor 160 may perform the white balancing by multiplying a weight constant, which is based on the first increasing rate, and the second image signals RL and RR together. Through the same method, there may be performed the white balancing for the third image signals. Below, the description associated with the third image signals will be omitted, but the third image signals may be processed by a method similar to that of the second image signals RL and RR.

Referring to FIG. 8B, the second image signal average code RS may be greater in value than the first image signal average code GS by the white balancing after the first exposure time GL_SAT. Depending on a photographing environment, the second image signal average code RS may be greater in value than the first image signal average code GS by the white balancing before and after the first exposure time GL_SAT. For convenience, the description will be given under the condition that the second image signal average code RS is greater in value than the first image signal average code GS by the white balancing after the first exposure time GL_SAT.

In this case, some of image signals output from the image signal processor 160 may have a red value greater than an actual red value due to the second image signal average code RS (or the average code of the second image signals RL and RR) excessively compensated by the white balancing. For example, some pixels of an output image may be expressed to be redder than the actual redness in a captured image. This phenomenon may be caused in an example case in which some of the second image signals RL and RR are converted into a very great value by the white balancing. For example, the above phenomenon may be caused in an example case in which some of the second image signals RL and RR are converted into a value exceeding a saturation level (e.g., 1023 when 10-bit digitization is made).

Accordingly, the image signal processor 160 may perform compensation CP1 of a color channel difference of image signals experiencing the white balancing. In an example case in which at least some of the second image signals RL and RR reach the saturation level, the image signal processor 160 may change values of the second image signals RL and RR reaching the saturation level. As a result, the image signal processor 160 may change at least some of the second image signals RL and RR such that the increasing rate of the second image signal average code RS is similar to the second increasing rate of the first image signal average code GS after the first exposure time GL_SAT.

FIG. 8C shows image signals experiencing the compensation CP1 of a color channel difference, which the image signal processor 160 performs on image signals of FIG. 8B.

Referring to FIG. 8C, the second image signal average code RS may be smaller in value than the first image signal average code GS after the second exposure time IPO_OF by the compensation CP1 of a color channel difference. For example, as overflowed charges moves to the unit pixels placed on the right side of the first pixel group through the overflow region IPO of FIGS. 4 and 5, after the second exposure time IPO_OF, the magnitude of the first image signal GR may increase with an increasing rate greater than an increasing rate before the second exposure time IPO_OF. For this reason, the above phenomenon may be caused.

In this case, some of image signals output from the image signal processor 160 may have a green value greater than an actual green value due to the first image signal average code GS (e.g., the average code of the first image signals GL and GR). For example, some pixels of an output image may be expressed to be greener than the actual green in a captured image.

Accordingly, the image signal processor 160 may perform compensation CP2 of a difference between image signals, which experience the compensation CP1 of a color channel difference, due to the overflow. According to embodiments of disclosure, the difference between image signals may be referred to as an “IPO difference”.

In an example case in which some (e.g., GL) of the first image signals GL and GR has the saturation level and the second image signals RL and RR are smaller than the other(s) (e.g., GR) of the first image signals GL and GR as much as a reference value, the image signal processor 160 may change values of at least some of the second image signals RL and RR. As a result, the image signal processor 160 may change at least some of the second image signals RL and RR such that the increasing rate of the second image signal average code RS is similar to the third increasing rate of the first image signal average code GS after the third exposure time GR_SAT. The reference value may be a preset value.

FIG. 8D shows image signals experiencing the compensation CP1 of a color channel difference and the compensation CP2 of an IPO difference, which the image signal processor 160 performs. It is confirmed from FIG. 8D that the linearity of the first image signal average code GS is similar to the linearity of the second image signal average code RS. Likewise, the linearity of the third image signal average code may be similar to the linearity of the first image signal average code GS.

Referring to FIGS. 8A to 8D, in an example case in which some (e.g., GL) of the first image signals GL and GR have the saturation level and the other(s) (e.g., GR) of the first image signals GL and GR does not reach the saturation level, the image signal processor 160 may change values of at least some of the second image signals RL and RR and/or the third image signals. For example, the image signal processor 160 may compensate for a color channel difference and/or an IPO difference which is caused in an example case in which only unit pixels placed on any one side from among the unit pixels of the first pixel groups PXG1A and PXG1B of FIG. 2 are saturated due to the disparity in the micro lens. The image signal processor 160 may compensate for a color channel difference and/or an IPO difference by changing at least some of image signals corresponding to unit pixels of the second pixel group PXG2 and/or the third pixel group PXG3 of FIG. 2.

FIG. 9 is a schematic block diagram of the image signal processor 160 according to an embodiment of the disclosure. The image signal processor 160 of FIG. 9 may correspond to the image signal processor 160 of FIG. 1.

Referring to FIG. 9, the image signal processor 160 may receive an image signal IDT and may output an image signal pIDT by performing one or more image processing operations for the image signal IDT.

In an embodiment, the image signal processor 160 may include a front end (FE) circuit 161, a compensation circuit 163, a formatting circuit 165, and an output interface circuit 167. However, the disclosure is not limited thereto, and as such, one or more components may be added to or omitted from the structure of the image signal processor 160 illustrated in FIG. 9.

The front end circuit 161 may perform operations including, but not limited to, noise processing and/or white balancing on the image signal IDT: noise processing and white balancing.

The compensation circuit 163 may perform operations including, but not limited to, the compensation CP1 of a color channel difference and the compensation CP2 of an IPO difference on the image signal IDT experiencing the white balancing.

The formatting circuit 165 may demosaic the image signal IDT experiencing the compensation CP1 of a color channel difference and the compensation CP2 of an IPO difference. According to an embodiment, the formatting circuit 165 may merge the image signal IDT experiencing the compensation CP1 of a color channel difference and the image signal IDT experiencing the compensation CP2 of an IPO difference. According to an embodiment, the compensation circuit 163 may perform demosaicing together with the compensation CP1 of a color channel difference and the compensation CP2 of an IPO difference. According to embodiments of the disclosure, the formatting circuit 165 may perform demosaicking. However, the technical idea of the disclosure is not limited thereto.

The output interface circuit 167 may transmit the image signal pIDT experiencing the image processing to the outside, based on a protocol of an output interface. For example, the output interface may exchange data with an external device based on a camera serial interface (CSI) and a C-PHY defined by a mobile industry processor interface (MIPI) alliance. The output interface is not limited to the CIS and the C-PHY.

FIGS. 10A and 10B are block diagrams describing a configuration of a compensation circuit according to an embodiment of the disclosure. Compensation circuits of FIGS. 10A and 10B may correspond to the compensation circuit 163 of FIG. 9.

Referring to FIG. 10A, the compensation circuit may perform the compensation CP1 of a color channel difference and the compensation CP2 of an IPO difference described with reference to FIGS. 8A to 8D. For example, the compensation circuit may sequentially perform the compensation CP1 of the color channel difference and the compensation CP2 of the IPO difference described with reference to FIGS. 8A to 8D.

The compensation circuit may include a color channel compensation circuit 163a and an IPO overflow compensation circuit 163b. The color channel compensation circuit 163a may receive the image signal IDT and perform the compensation CP1 of a color channel difference on the image signal IDT. The IPO overflow compensation circuit 163b may perform the compensation CP2 of an IPO difference on an image signal cIDT experiencing the compensation CP1 of a color channel difference.

Referring to FIG. 10B, the compensation circuit may perform the compensation CP1 of a color channel difference and the compensation CP2 of an IPO difference in parallel. The compensation circuit may include the color channel compensation circuit 163a, which receives the image signal IDT experiencing the white balancing and performs the compensation CP1 of a color channel difference, and the IPO overflow compensation circuit 163b, which receives the image signal IDT experiencing the white balancing and performs the compensation CP2 of an IPO difference. The compensation circuit may further include an image signal merge circuit 163c which merges the image signal cIDT experiencing the compensation CP1 of a color channel difference and an image signal iIDT experiencing the compensation CP2 of an IPO difference.

FIGS. 10A, 10B, and 11 to 16 will be described under the condition that the compensation circuit performs the compensation CP2 of an IPO difference on image signals experiencing the compensation CP1 of a color channel difference, but the technical idea of the disclosure is not limited thereto.

FIG. 11 is a block diagram describing the color channel compensation circuit 163a of an image signal processor according to an embodiment of the disclosure. The color channel compensation circuit 163a may correspond to the compensation circuit 163 of FIGS. 10A and 10B.

Referring to FIG. 11, in an embodiment, the color channel compensation circuit 163a may include a first saturation level determination circuit 163_1, a clipping circuit 163_2, and a selection circuit 163_3. However, the disclosure is not limited thereto, and as such, one or more components may be added to or omitted from the structure of the color channel compensation circuit 163a illustrated in FIG. 11.

According to an embodiment, an image signal wIDT experiencing the white balancing may be input to the first saturation level determination circuit 163_1, the clipping circuit 163_2, and the selection circuit 163_3.

The first saturation level determination circuit 163_1 may compare a magnitude of the image signal wIDT experiencing the white balancing with a magnitude of a clipped image signal cpIDT obtained by clipping the image signal wIDT based on the saturation level. The first saturation level determination circuit 163_1 may transmit a control signal DS to the selection circuit 163_3 based on a comparing result.

The clipping circuit 163_2 may perform clipping on the image signal wIDT experiencing the white balancing based on the saturation level. In an example case in which the readout circuit 150 of FIG. 1 performs 10-bit digital conversion on a pixel signal, the clipping circuit 163_2 may change the image signal wIDT to have a value, which is smaller of 1023 (which is the maximum value capable of being expressed by 10 bits) and a value of the image signal wIDT and may output the clipped image signal cpIDT.

The selection circuit 163_3 may output any one of the clipped image signal cpIDT and the image signal wIDT experiencing the white balancing as an image signal chIDT experiencing the compensation CP1 of a color channel difference, based on the control signal DS.

FIG. 12 is a diagram describing the compensation CP1 of a color channel difference which a color channel compensation circuit performs, according to an embodiment of the disclosure. The compensation CP1 of a color channel difference may be performed by the color channel compensation circuit 163a of FIG. 11. According to an embodiment, a manner in which the color channel compensation circuit 163a performs the compensation CP1 of a color channel difference will be described with reference to FIGS. 12 and 13.

The color channel compensation circuit 163a may perform the compensation CP1 of a color channel difference for respective image signals of target pixels of a region of interest.

The region of interest may include unit pixels, which are within a preset range from a target pixel PS targeted for the compensation CP1 of a color channel difference, from among the unit pixels of the pixel array.

According to an embodiment, referring to FIG. 12, the region of interest may be a first region of interest ROI1 in which unit pixels present within a given range from the target pixel PS are included. According to another embodiment, the region of interest may be a second region of interest ROI2 corresponding to pixel units PXU1, PXU2, PXU3, PXU4, PXY6, PXU7, PXU8, and PXU9 surrounding a pixel unit PXUS in which the target pixel PS is included. In FIGS. 12 to 16, the description will be given under the condition that the region of interest corresponds to the second region of interest ROI2. However, according to an embodiment, the size of the region of interest may be differently set.

Image signals of unit pixels corresponding to the region of interest may be stored in a memory device. The selection circuit 163_3 may perform the compensation CP1 of a color channel difference on the image signals by referring to a line memory device. The description will be given under the condition that the image signals stored in the line memory device are image signals experiencing the white balancing.

The clipping circuit 163_2 may output the clipped image signal cpIDT by comparing the image signal wIDT of the target pixel PS with the saturation level and changing the image signal wIDT so as to have the smaller value, among the saturation level and a value of the image signal wIDT of the target pixel PS.

In an embodiment, the first saturation level determination circuit 163_1 may determine or select unit pixels (e.g., comparison pixels), each having a color channel that is identical to a color channel corresponding to the target pixel PS. For example, the comparison pixels may be unit pixels included in a pixel group of a type, which is identical to that of the target pixel PS. The comparison pixels may include the target pixel PS. For example, the comparison pixels may be unit pixels R1, R2, R3, and R4 of each of the pixel units PXU1, PXU2, PXU3, PXU4, PXU5, PXU6, PXU7, PXU8, and PXU9.

In an embodiment, the first saturation level determination circuit 163_1 may determine or select unit pixels (e.g., comparison pixels), each having a phase that is identical to that of the target pixel PS and whose color channel is identical to a color channel of the target pixel PS. The comparison pixels may include the target pixel PS. For example, the comparison pixels may be pixels R1 respectively included in the pixel PXU1, PXU2, PXU3, PXU4, PXU5, PXU6, PXU7, PXU8, and PXU9.

In an embodiment, the first saturation level determination circuit 163_1 may determine or select unit pixels (e.g., comparison pixels), each having a color channel that is identical to a color channel corresponding to the target pixel PS and which are at the same location in each of pixel units. The comparison pixels may include the target pixel PS. For example, the comparison pixels may be pixels R1 and R3 of each of the pixel PXU1, PXU2, PXU3, PXU4, PXU5, PXU6, PXU7, PXU8, and PXU9.

According to an embodiment, the first saturation level determination circuit 163_1 may compare a magnitude of an average of the image signals wIDT of the comparison pixels and a magnitude of an average of the clipped image signals cpIDT of the comparison pixels. According to another embodiment, the first saturation level determination circuit 163_1 may compare a magnitude of a sum of the image signals wIDT of the comparison pixels and a magnitude of a sum of the clipped image signals cpIDT of the comparison pixels. The first saturation level determination circuit 163_1 may output a comparison result as the control signal DS.

The selection circuit 163_3 may output an image signal having a smaller magnitude from among the clipped image signal cpIDT and the image signal wIDT experiencing the white balancing as the image signal chIDT experiencing the compensation CP1 of a color channel difference, based on the control signal DS. In an example case in which the average of the image signals wIDT of the comparison pixels is smaller than the average of the clipped image signals cpIDT of the comparison pixels, the selection circuit 163_3 may output the image signal wIDT of the target pixel PS as the image signal chIDT experiencing the compensation CP1 of a color channel difference.

FIG. 13 is a block diagram describing the IPO overflow compensation circuit 163b of an image signal processor according to an embodiment of the disclosure. The IPO overflow compensation circuit 163b may correspond to the IPO overflow compensation circuit IPO 163b of FIGS. 10A and 10B.

In an embodiment, referring to FIG. 13, the IPO overflow compensation circuit 163b may include a first UV level determination circuit 163_4, a second saturation level determination circuit 163_5, a second UV level determination circuit 163_6, and a merge circuit 163_7. However, the disclosure is not limited thereto, and as such, one or more components may be added to or omitted from the structure of IPO overflow compensation circuit 163b illustrated in FIG. 13.

Each of the first UV level determination circuit 163_4, the second saturation level selection circuit 163_5, and the second UV level determination circuit 163_6 may receive the image signal chIDT experiencing the compensation CP1 of a color channel difference. In the description given with reference to FIG. 13, the image signal chIDT experiencing the compensation CP1 of a color channel difference may be simply referred to as a “target image signal chIDT”. A unit pixel corresponding to the target image signal chIDT may be referred to as a “target pixel”.

The first UV level determination circuit 163_4 may compare a value, which is obtained by summing some of V signals and U signals based on the target image signal chIDT of the region of interest, with a first threshold value and may output a first result WW1 as a comparison result.

The U signals and the V signals may be based on YUV encoding. According to embodiments of the disclosure, the Y signal includes the same code value as an image signal of the green color channel, the U signal includes a code value corresponding to a difference between an image signal of the blue color channel and an image signal of the green color channel, and the V signal includes a code value corresponding to a difference between an image signal of the red color channel and an image signal of the green color channel. However, the disclosure is not limited thereto, and as such, according to another embodiment, the Y signal, the U signal, and the V signal may be based on a method different from the above method, and the Y signal, the U signal, and the V signal may be included in the technical idea of the disclosure as long as the Y signal, the U signal, and the V signal are based on the YUV encoding.

In an embodiment, the first UV level determination circuit 163_4 may compare a value (e.g., an absolute value), which is obtained by summing U signals and V signals of unit pixels (e.g., comparison pixels) provided at a location(s) different from that of a target pixel in pixel groups, with the first threshold value and may output the first result WW1 as a comparison result. In an example case in which the target pixel is placed on the right side of the pixel group, the first UV level determination circuit 163_4 may compare a value, which is obtained by summing U signals and V signals of unit pixels placed on the left side of pixel groups, with the first threshold voltage.

In an embodiment, the first UV level determination circuit 163_4 may compare a value (e.g., an absolute value), which is obtained by summing U signals and V signals of unit pixels (e.g., comparison pixels) provided at a location(s) different from that of a target pixel in pixel groups corresponding to the same color channel as the target pixel, with the first threshold value and may output the first result WW1 as a comparison result. In an example case in which the target pixel is a unit pixel placed on the left side of the second pixel group, the first UV level determination circuit 163_4 may compare a value, which is obtained by summing U signals and V signals of unit pixels placed on the right side of the second pixel groups in the region of interest, with the first threshold voltage.

The first threshold voltage may be set based on consideration that the majority of image signals of the corresponding unit pixels reach the saturation level. Accordingly, referring to FIG. 8C, the first UV level determination circuit 163_4 may determine whether the target image signal chIDT has a corresponding code after the first exposure time GL_SAT. In an example case in which the target pixel is a unit pixel of the second pixel group, unit pixels placed at a location(s) different from that of the target pixel in the second pixel group may have a code similar to the saturation level by the white balancing. Also, image signals corresponding to the first unit pixels placed on any one side in the first pixel group from among the first image signals may have a code reaching the saturation level. Accordingly, in an example case in which the value (e.g., an absolute value) obtained by summing the U signals and the V signals of the comparison pixels is smaller than the first threshold voltage, it may be determined that the target image signal chIDT has a corresponding code after the first exposure time GL_SAT.

The second saturation level selection circuit 163_5 may compare a value, which is obtained by summing or averaging image signals of at least some unit pixels (or comparison pixels) of the first pixel groups in the region of interest, with a second threshold voltage and may output a second result WW2 as a comparison result.

In an embodiment, the second saturation level selection circuit 163_5 may compare a value, which is obtained by summing or averaging image signals of all the unit pixels (or comparison pixels) of the first pixel groups in the region of interest, with the second threshold voltage and may output the second result WW2 as a comparison result.

The second saturation level selection circuit 163_5 may compare a value, which is obtained by summing or averaging image signals of unit pixels (or comparison pixels) provided at the same location as the target pixel in the first pixel groups in the region of interest, with the second threshold voltage and may output the second result WW2 as a comparison result.

The second threshold voltage may be set based on a consideration that the majority of image signals of the corresponding unit pixels reach the saturation level. Accordingly, referring to FIG. 8C, the second saturation level selection circuit 163_5 may determine whether the target image signal chIDT has a corresponding code after the first exposure time GL_SAT. For example, in a case in which the value (e.g., an average value) obtained by summing the image signals of the comparison pixels is greater than the second threshold voltage, it may be determined that the target image signal chIDT has a corresponding code after the first exposure time GL_SAT. For example, the region of interest may correspond to the second region of interest ROI2 of FIG. 12, and the second threshold voltage for comparing the average value of the image signals of the comparison pixels may be 999 or more.

The second UV level determination circuit 163_6 may compare a value, which is obtained by summing some of V signals and U signals based on the target image signal chIDT of the region of interest, with a third threshold value and may output a third result WW3 as a comparison result.

In an embodiment, the second UV level determination circuit 163_6 may compare a value (e.g., an absolute value), which is obtained by summing U signals and V signals of unit pixels (e.g., comparison pixels) provided at the same location as the target pixel in pixel groups, with the third threshold value and may output the third result WW3 as a comparison result. For example, the second UV level determination circuit 163_6 may compare a value, which is obtained by summing U signals and V signals of unit pixels placed on the left side of pixel groups, with the third threshold voltage.

In an embodiment, the second UV level determination circuit 163_6 may compare a value (e.g., an absolute value), which is obtained by summing U signals and V signals of unit pixels (e.g., comparison pixels) provided at the same location as the target pixel in pixel groups corresponding to the same color channel as the target pixel, with the third threshold value and may output the third result WW3 as a comparison result. In an example case in which the target pixel is a unit pixel placed on the left side of the second pixel group, the second UV level determination circuit 163_6 may compare a value, which is obtained by summing U signals and V signals of unit pixels placed on the left side of the second pixel groups in the region of interest, with the third threshold voltage.

The third threshold voltage may be set based on a consideration that a difference between the majority of image signals of comparison pixels and first image signals (e.g., image signals of the first pixel group) is great. Accordingly, referring to FIG. 8C, the second UV level determination circuit 163_6 may determine whether the target image signal chIDT has a corresponding code after the second exposure time IPO_OF. For example, in a case in which the value (e.g., an absolute value) obtained by summing the U signals and the V signals of the comparison pixels is greater than the third threshold voltage, it may be determined that the target image signal chIDT has a corresponding code after the second exposure time IPO_OF.

The merge circuit 163_7 may determine whether the target image signal chIDT has a corresponding code after the second exposure time IPO_OF of FIG. 8C, based on all of the first result WW1, the second result WW2, and the third result WW3. In an example case in which it is determined that the target image signal chIDT has a corresponding code after the second exposure time IPO_OF of FIG. 8C, the merge circuit 163_7 may change the target image signal chIDT to the first image signal corresponding to the target pixel.

For example, the merge circuit 163_7 may calculate an average value of image signals of the first unit pixels placed at the same row as the target pixel, having the same phase as the target pixel, and being the closest to the target pixel. The merge circuit 163_7 may change the target image signal chIDT so as to have the average value of the image signals of the first unit pixels.

In an example case in which the target image signal chIDT does not have a corresponding code after the second exposure time IPO_OF of FIG. 8C, the merge circuit 163_7 may output the target image signal chIDT without modification.

In an example case in which it is determined that the target image signal chIDT has a corresponding code after the second exposure time IPO_OF of FIG. 8C, the IPO overflow compensation circuit 163b may change the target image signal chIDT to the corresponding first image signal. As a result, the increasing rate of the second image signal (e.g., an image signal of a unit pixel included in the second pixel group) and/or the third image signal (e.g., an image signal of a unit pixel included in the third pixel group) may be changed to be similar to the increasing rate of the first image signal (e.g., an image signal of a unit pixel included in the first pixel group).

FIGS. 14 to 16 are diagrams describing the compensation CP2 of an IPO difference which an IPO overflow compensation circuit performs, according to an embodiment of the disclosure.

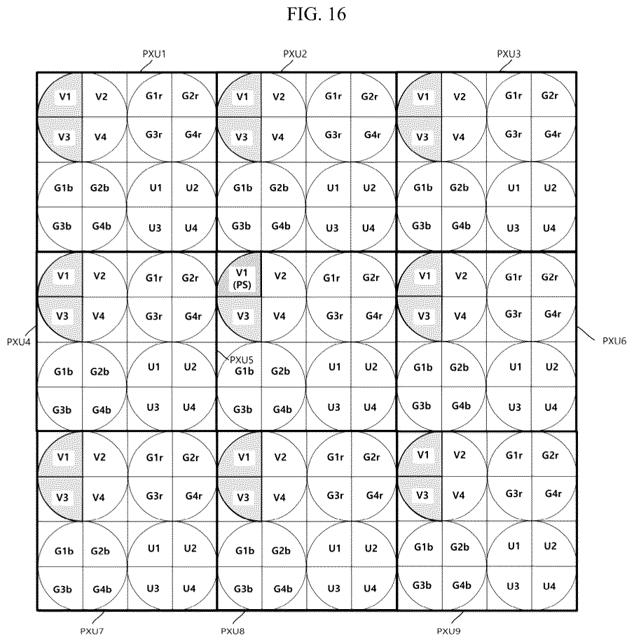

The compensation CP2 of an IPO difference may be performed by the IPO overflow compensation circuit 163b of FIG. 13. According to an embodiment, a manner in which the IPO overflow compensation circuit 163b performs the compensation CP2 of an IPO difference will be described with reference to FIGS. 13 and 16.

The IPO overflow compensation circuit 163b may perform the compensation CP2 of an IPO difference for respective image signals of target pixels of a region of interest.

The region of interest may include unit pixels within a preset range from the target pixel PS, as described with reference to FIG. 12.

FIG. 14 illustrates a method of deciding a V signal in the YUV signal. According to an embodiment, the V signal may be determined in advance by a separate circuit. According to another embodiment, the IPO overflow compensation circuit 163b may determine the V signal. A method of deciding the U signal is similar to the method of deciding the V signal. The description will be given under the condition that the V signal includes a code value corresponding to a difference between an image signal of the red color channel and an image signal of the green color channel and the Y signal includes a code value of the image signal of the green color channel.

Referring to FIG. 14, in an embodiment, the V signal corresponding to a target pixel PS1 may be based on image signals of the first unit pixels placed at the same row as the target pixel PS1, having the same phase as the target pixel PS1, and being the closest to the target pixel PS1. For example, the first unit pixels placed at the same row as the target pixel PS1, having the same phase as the target pixel PS1, and being the closest to the target pixel PS1 may have Y signals of Y1 and Y3. The Y signal corresponding to the target pixel PS1 may be calculated as Y2 being an average value of Y1 and Y3, and a code value of the image signal of the green color channel corresponding to the target pixel PS1 may also be calculated as Y2. Accordingly, the V signal of the target pixel PS1 may be based on a difference between Y2 and an image signal of the target pixel PS1.

In an embodiment, the V signal corresponding to the target pixel PS1 may be based on image signals of the first unit pixels placed at the same row as the target pixel PS2 and being the closest to the target pixel PS2. For example, the first unit pixels placed at the same row as the target pixel PS2, having the same phase as the target pixel PS2, and being the closest to the target pixel PS2 may have Y signals of Y4 and Y6. For example, Y5 may be an average value of Y4 and Y6 may correspond to a central location of the target pixel PS2 and a pixel placed on the right side of the target pixel PS2 (e.g., a location where the target pixel PS2 is in contact with a pixel placed on the right side of the target pixel PS2). According to an embodiment, another image signal Rmid corresponding to the central location of the target pixel PS2 and the pixel placed on the right side of the target pixel PS2 may be calculated as an average of an image signal of the target pixel PS2 and an image signal of the pixel placed on the right side of the target pixel PS2. Accordingly, the V signal corresponding to the central location of the target pixel PS2 and the pixel placed on the right side of the target pixel PS2 may be calculated as a difference between Y5 and Rmid. The V signal of the target pixel PS1 may be calculated as a difference between Y5 and Rmid or may be calculated as a difference between Y5 and the image signal of the target pixel PS2.

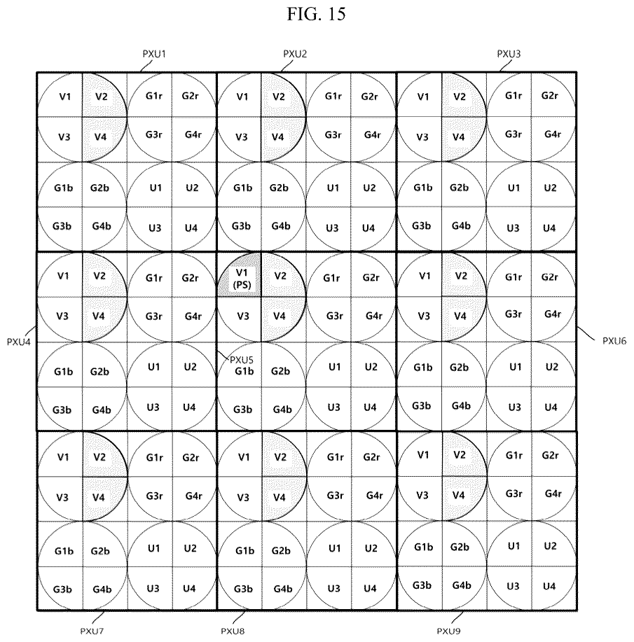

FIG. 15 is a diagram describing an operation of the first UV level determination circuit 163_4 according to an embodiment of the disclosure. An operation of the first UV level determination circuit 163_4 will be described with reference to FIGS. 13 and 15.

The first UV level determination circuit 163_4 may compare a value, which is obtained by summing some of V signals and U signals based on a target image signal of a region of interest, with the first threshold value and may output the first result WW1 as a comparison result. The target image signal may be an image signal of the target pixel PS.

The first UV level determination circuit 163_4 may output the first result WW1 for respective image signals of target pixels of the region of interest.

The region of interest may include unit pixels, which are within a preset range from the target pixel PS targeted for the compensation CP2 of an IPO difference, from among the unit pixels of the pixel array.

In an embodiment, FIG. 15 will be described under the condition that the first UV level determination circuit 163_4 compares a value (e.g., an absolute value), which is obtained by summing U signals and V signals of unit pixels (e.g., comparison pixels) provided at a location(s) different from that of a target pixel in pixel groups corresponding to the same color channel as the target pixel, with the first threshold value and may output the first result WW1 as a comparison result.

Referring to FIG. 15, the target pixel PS may be a unit pixel placed on the left side of the first pixel group of the fourth pixel unit PXU5. The first UV level determination circuit 163_4 may determine or select unit pixels placed on the right side of the first pixel groups respectively included in the pixel units PXU1, PXU2, PXU3, PXU4, PXU5, PXU6, PXU7, PXU8, and PXU9 as comparison pixels. The first UV level determination circuit 163_4 may compare a value (e.g., an absolute value), which is obtained by summing V signals V2 and V4 of the first pixel groups, with the first threshold value and may output the first result WW1 as a comparison result.

FIG. 16 is a diagram describing an operation of the second UV level determination circuit 163_6 according to an embodiment of the disclosure. An operation of the second UV level determination circuit 163_6 will be described with reference to FIGS. 13 and 16.

The second UV level determination circuit 163_6 may compare a value, which is obtained by summing some of V signals and U signals based on a target image signal of a region of interest, with the third threshold value and may output the third result WW3 as a comparison result. The target image signal may be an image signal of the target pixel PS.

The second UV level determination circuit 163_6 may output the third result WW3 for respective image signals of target pixels of the region of interest.

The region of interest may include unit pixels, which are within a preset range from the target pixel PS targeted for the compensation CP2 of an IPO difference, from among the unit pixels of the pixel array.

In an embodiment, FIG. 16 will be described under the condition that the second UV level determination circuit 163_6 compares a value (e.g., an absolute value), which is obtained by summing U signals and V signals of unit pixels (e.g., comparison pixels) provided at the same location as the target pixel in pixel groups corresponding to the same color channel as the target pixel, with the third threshold value and may output the third result WW3 as a comparison result.

Referring to FIG. 16, the target pixel PS is a unit pixel placed on the left side of the first pixel group of the fourth pixel unit PXU5. The second UV level determination circuit 163_6 may determine or select unit pixels placed on the left side of the first pixel groups of each of the pixel units PXU1, PXU2, PXU3, PXU4, PXU5, PXU6, PXU7, PXU8, and PXU9 as comparison pixels. The second UV level determination circuit 163_6 may compare a value (e.g., an absolute value), which is obtained by summing V signals V1 and V3 of the first pixel groups, with the third threshold value and may output the third result WW3 as a comparison result.

FIG. 17 is a block diagram of an image sensor 100a according to an embodiment of the disclosure. Components which are the same as those described with reference to the above drawings will be omitted to avoid redundancy.

The image sensor 100a may include a first substrate 10a and a second substrate 20a which are stacked. The first substrate 10a and the second substrate 20a may be connected to each other through a wafer bonding process using a C2C interconnection of a pixel group level. The first substrate 10a and the second substrate 20a may be electrically connected even through a Cu-to-Cu (C2C) array placed in a peripheral region of a substrate, in addition to an in-pixel contact IN_CT within a unit pixel or a pixel group PXa. Control signals for controlling a pixel circuit may be transmitted through the C2C array. A pixel signal (or an image signal) of the first substrate 10a may be transmitted to a readout circuit (or an image processing processor) of the second substrate 20a through the in-pixel contact IN_CT.

FIG. 18 is a block diagram of an image sensor 100b according to an embodiment of the disclosure. Components which are the same as those described with reference to the above drawings will be omitted to avoid redundancy.

Referring to FIG. 18, the image sensor 100b may include a first substrate 10b, a second substrate 20b, and a third substrate 30b. The third substrate 30b, the second substrate 20b, and the first substrate 10b may be sequentially stacked in a direction D3 perpendicular to a plane of a substrate (e.g., a plane parallel to D1 and D2).

In an embodiment, some of pixel circuits PXb_1, PXb_2, and PXb_3 may be formed in each of the first substrate 10b and the second substrate 20b. A first partial circuit PBb_1 of the pixel group may be placed in the first substrate 10b, and a second partial circuit PXb_2 and a third partial circuit PXb_3 of the pixel group may be placed in the second substrate 20b. The third substrate 30b may include a readout circuit, a timing controller, logic such as an image processing processor, and an interface circuit. The readout circuit may include an ADC.

For example, a photodiode and a transfer transistor may be placed in the first substrate 10b, and the remaining pixel circuits may be placed in the second substrate 20b.

The shape where some of pixel circuits are provided in the first substrate 10b and the second substrate 20b is not limited thereto.

The first substrate 10b and the second substrate 20b may be electrically connected to each other.

In an embodiment, the first substrate 10b and the second substrate 20b may transmit a pixel signal or a control signal through a through silicon via TSV placed in a peripheral region of a substrate.

In an embodiment, the first partial circuit PXa_1 of the pixel group of the first substrate 10b and the second partial circuit PXb_2 of the pixel group of the second substrate 20b may also be electrically connected through a first inter-substrate connection structure INTC1. The first inter-substrate connection structure INTC1 may be a Cu-to-Cu (C2C) bonding contact, deep-contact structure. The deep contact structure may include a through silicon via. The first inter-substrate connection structure INTC1 may electrically connect an in-pixel contact IN_CT1 electrically connected to an element of the first partial circuit PXa_1 of the pixel group and an in-pixel contact IN_CT2 electrically connected to an element of the second partial circuit PXb_2 of the pixel group.

In an embodiment, the first substrate 10b and/or the second substrate 20b may be electrically connected to the third substrate 30b through the through silicon via TSV and a second inter-substrate connection structure INTC2. A signal of the first substrate 10b and/or the second substrate 20b may be transmitted to the readout circuit (or the image processing processor) of the third substrate 30b through the through silicon via TSV and/or the second inter-substrate connection structure INTC2.

In an embodiment, the second partial circuit PXb_2 of the pixel group may be electrically connected to circuits of the third substrate 30b through the Cu-to-Cu (C2C) bonding contact. The second inter-substrate connection structure INTC_2 may be the Cu-to-Cu (C2C) bonding contact.

In an embodiment, the third partial circuit PXb_3 of the pixel group may be electrically connected to the circuits of the third substrate 30b through a thru-silicon copper (TSC).

FIG. 19 is a block diagram of an electronic device according to an embodiment of the disclosure. Components which are the same as those described with reference to the above drawings will be omitted to avoid redundancy.

An electronic device 1000 may include a photographing part 1100, an image sensor 1200, a processor 1300, a display device 1400, and a storage device 1500.

The processor 1300 may control all the operations of the electronic device 1000. The processor 1300 may provide a control signal to a lens driving part (e.g., actuator) 1120 to control a location of a lens 1110. Accordingly, a focal length may be controlled.

The photographing part 1100 which is a component receiving a light may include the lens 1110 and the lens driving part 1120. The lens 1110 may include a plurality of lenses.

The lens driving part 1120 may move the lens 1110 in a direction in which a distance from an object “S” increases or decreases, based on the control signal of the processor 1300.

The image sensor 1200 may generate an image signal and/or phase data based on an incident light. The image sensor 1200 may include a pixel array 1210, a timing controller 1220, a readout circuit 1230, and an image signal processor 1240.

Pixel groups of the pixel array 1210 may include at least one photoelectric conversion element.

Each of the pixel groups of the pixel array 1210 according to an embodiment of the disclosure may share the same micro lens. Some of pixel groups may include an overflow region. The image signal processor 1240 may perform compensation of a color channel difference or IPO compensation on image signals transmitted from the readout circuit 1230.

The image signal processor 1240 may generate a mode control signal MC based on a photographing mode signal MODE which the processor 1300 transmits. The pixel groups may operate in the signal output mode for each unit pixel PX or the signal output mode for each pixel group PXG, based on the mode control signal MC which the image signal processor 1240 transmits.

The image signal processor 1240 may provide the mode control signal MC to the timing controller 1220. The timing controller 1220 may control an operation of the pixel array 1210 based on the mode control signal MC.

FIG. 20 is a flowchart illustrating an operating method of an image sensor according to an embodiment of the disclosure. Components which are the same as those described with reference to the above drawings will be omitted to avoid redundancy. The operating method of the image sensor of FIG. 20 may be performed by the image sensor 100 of FIG. 1.

In operation S110, the method may include obtaining an image signal. For example, a pixel array of the image sensor 100 may output the pixel signal, and a readout circuit may output the image signal based on the pixel signal.

In operation S120, the method may include performing compensation of a color channel difference of an image signal. For example, an image signal processor of the image sensor 100 may perform compensation of a color channel difference of an image signal.

For example, the color channel compensation circuit 163a of FIG. 11 may perform compensation of a color channel difference of an image signal as described with reference to FIGS. 11 and 12.

In operation S130, the method may include performing IPO compensation of an image signal. For example, the image signal processor of the image sensor 100 may perform IPO compensation of an image signal.

For example, the IPO overflow compensation circuit 163b of FIG. 13 may perform IPO compensation of an image signal as described with reference to FIGS. 13 and 16.

An image sensor according to the disclosure may compensate for a difference between image signals due to a disparity of a micro lens.

The image sensor according to the disclosure may compensate for a difference between image signal based on a plurality of pixels sharing a micro lens.

The image sensor according to the disclosure may generate an image signal experiencing compensation of a color-specific difference due to a disparity of a micro lens.

Although the description above of the image sensor according to some embodiments were in terms of circuits, the disclosure is not limited thereto. As such, the image sensor and/or other devices according to various embodiments may be described and illustrated in terms of blocks which carry out a described function or functions. These blocks, which may be referred to herein as managers, units, modules, hardware components or the like, are physically implemented by analog and/or digital circuits such as logic gates, integrated circuits, microprocessors, microcontrollers, memory circuits, passive electronic components, active electronic components, optical components, hardwired circuits and the like, and may optionally be driven by a firmware. The circuits may, for example, be embodied in one or more semiconductor chips, or on substrate supports such as printed circuit boards and the like. The circuits constituting a block may be implemented by dedicated hardware, or by a processor (e.g., one or more programmed microprocessors and associated circuitry), or by a combination of dedicated hardware to perform some functions of the block and a processor to perform other functions of the block. Each block of the embodiments may be physically separated into two or more interacting and discrete blocks without departing from the scope of the disclosure. Likewise, the blocks of the embodiments may be physically combined into more complex blocks without departing from the scope of the disclosure. However, the disclosure is not limited thereto, and as such, the blocks, which may be referred to herein as managers, units, modules, or the like, may be software modules implemented by software codes, program codes, software instructions, or the like. The software modules may be executed on one or more processors.

While the disclosure has been described with reference to embodiments thereof, it will be apparent to those of ordinary skill in the art that various changes and modifications may be made thereto without departing from the spirit and scope of the disclosure as set forth in the following claims.

What is claimed is:

1. An image sensor comprising:
a pixel array comprising first pixel groups, second pixel groups, and third pixel groups arranged in a matrix shape, each of the first pixel groups comprising a plurality of first unit pixels and a first color filter corresponding to a first color, each of the second pixel groups comprising a plurality of second unit pixels and a second color filter corresponding to a second color, each of the third pixel groups comprising a plurality of third unit pixels and a third color filter corresponding to a third color;
a readout circuit configured to output image signals based on pixel signals output from the pixel array; and
an image signal processor configured to perform one or more image processing operations on the image signals and output image-processed image signals,
wherein the image signal processor is further configured to change a target image signal corresponding to a target pixel based on saturation of one or more first first unit pixels among the plurality of first unit pixels in a region of interest, and
wherein the target pixel is a second unit pixel, among the plurality of second unit pixels or a third unit pixel, among the plurality of third unit pixels.

2. The image sensor of claim 1, wherein the image signal processor is further configured to change the target image signal based on the saturation of the one or more first first unit pixels provided on a first side respectively in each of one or more of the first pixel groups in the region of interest and non-saturation of one or more second first unit pixels among the plurality of first unit pixels provided on a second side respectively in each of the one or more of the first pixel groups in the region of interest.

3. The image sensor of claim 1, wherein each of the first pixel groups comprises:
an overflow region in contact with a plurality of photodiodes respectively included in the plurality of first unit pixels, the overflow region configured to provide a transfer path of overflowed charges between the plurality of photodiodes of the plurality of first unit pixels, and
wherein the image signal processor is further configured to change the target image signal based on overflow of charges through the overflow region between the plurality of first unit pixels.

4. The image sensor of claim 3, wherein the image signal processor is further configured to change the target image signal, based on a result of summing magnitudes of at least some of U signals or V signals which are based on the image signals corresponding to unit pixels in the region of interest, and
wherein the U signals and the V signals are based on YUV encoding.

5. The image sensor of claim 4, wherein the image signal processor is further configured to change the target image signal, based on a result of summing magnitudes of the U signals or the V signals corresponding to unit pixels provided in a first side within each of the first pixel groups, the second pixel groups, and the third pixel groups in the region of interest.

6. The image sensor of claim 3, wherein the image signal processor is further configured to change the target image signal, based on at least some of image signals corresponding to the plurality of first unit pixels in the region of interest reach a saturation level.

7. The image sensor of claim 3, wherein the image signal processor is further configured to change the target image signal, based on image signals of the plurality of first unit pixels in the region of interest.

8. The image sensor of claim 1, wherein a plurality of unit pixels of a same pixel group of the first pixel groups, the second pixel groups, and the third pixel groups share one micro lens,
wherein the plurality of unit pixels of the same pixel group generate charges based on a light passing through a color filter corresponding to a same color channel, and
wherein color filters placed in pixel groups adjacent to each other from among the first pixel groups, the second pixel groups, and the third pixel groups transmit lights of different spectra.

9. The image sensor of claim 1, wherein the image signal processor is further configured to change the target image signal, based on magnitudes of image signals of pixel groups having color filters identical to a color filter of the target pixel in the region of interest.

10. The image sensor of claim 9, wherein the image signal processor is further configured to change the target image signal, based on comparison of a first value and a second value,
wherein the first value is obtained by summing image signals of pixel groups having a color filter identical to a color filter of the target pixel in the region of interest, and
wherein the second value corresponds to a sum of values obtained by clipping, based on a saturation level, the image signals of the pixel groups having the color filter identical to the color filter of the target pixel in the region of interest.

11. An image sensor comprising:
a pixel array comprising first pixel groups, second pixel groups, and third pixel groups are arranged in a matrix shape, each of the first pixel groups comprising a plurality of first unit pixels and a first color filter corresponding to a first color, each of the second pixel groups comprising a plurality of second unit pixels and a second color filter corresponding to a second color, each of the third pixel groups comprising a plurality of third unit pixels and a third color filter corresponding to a third color;
a readout circuit configured to output image signals, based on pixel signals output from the pixel array; and
an image signal processor configured to:
generate first image signals, second image signals, and third image signals by performing white balancing of the image signals, and
change at least one of the second image signals and the third image signals based on saturation of one or more first first unit pixels among the plurality of first unit pixels of the first pixel groups and non-saturation of one or more second first unit pixels among the plurality of first unit pixels of the first pixel groups,
wherein the first image signals are based on pixel signals of the plurality of first unit pixels of the first pixel groups, the second image signals are based on pixel signals of the plurality of second unit pixels of the second pixel groups, and the third image signals are based on pixel signals of the plurality of third unit pixels of the third pixel groups.

12. The image sensor of claim 11, wherein the color filter of each of the first pixel groups corresponds to a green color filter, the color filter of each of the second pixel groups corresponds to a red color filter, and the color filter of each of the third pixel groups corresponds to a blue color filter,
wherein the first pixel groups, the second pixel groups, and the third pixel groups are arranged in the pixel array in the shape of a Bayer pattern, and
wherein a plurality of unit pixels in a same pixel group share one micro lens.

13. The image sensor of claim 11, wherein the image signal processor is further configured to:
change one or more of the second image signals based on the one or more of the second image signals reaching a saturation level; or
change one or more of the third image signals based on one or more of the third image signals reach the saturation level.

14. The image sensor of claim 11, wherein the image signal processor is further configured to change one or more the second image signals and the third image signals based on overflow of charges through an overflow region between the plurality of first unit pixels, and
wherein the overflow region is in contact with photodiodes of the plurality of first unit pixels and provides a transfer path of overflowed charges between the photodiodes of the plurality of first unit pixels.

15. The image sensor of claim 14, wherein the image signal processor is further configured to the change one or more of the second image signals or the third image signals not reaching the saturation level, based on the first image signals.

16. The image sensor of claim 15, wherein the image signal processor is further configured to change the one or more the second image signals or the third image signals not reaching the saturation level, based on the first image signals corresponding to unit pixels not saturated from among the plurality of first unit pixels.

17. An image sensor comprising:
a pixel array comprising a plurality of pixel groups arranged in a matrix shape;
a readout circuit configured to output image signals, based on pixel signals output from the pixel array; and
an image signal processor configured to:
generate first image signals, second image signals, and third image signals by performing white balancing of the image signals, and
output processed image signals obtained by changing at least one of the second image signals and the third image signals based on one or more of the first image signals, the second image signals, and the third image signals reaching a saturation level,
wherein the plurality of pixel groups comprise a first pixel group, a second pixel group, and a third pixel group associated with different color channels, and
wherein the first image signals are based on a pixel signal of a first pixel groups, the second image signals are based on a pixel signal of a second pixel groups, and third image signals are based on a pixel signal of a third pixel groups.

18. The image sensor of claim 17, wherein the first pixel group comprises first unit pixels, the second pixel group comprises second unit pixels, and the third pixel group comprises third unit pixels,
wherein the first pixel group further comprises an overflow region being in contact with photodiodes of the first unit pixels, the overflow region configured to provide a transfer path of overflowed charges between the photodiodes of the first unit pixels.

19. The image sensor of claim 18, wherein the image signal processor is further configured to change at least some of the second image signals and the third image signals based on an overflow of charges through the overflow region between the first unit pixels.

20. The image sensor of claim 19, wherein the image signal processor is further configured to change at least some of the second image signals or the third image signals based on a first result of determining that at least some of the first image signals corresponding to a region of interest of a first size reach the saturation level, and a second result of comparing the second image signals and the third image signals corresponding to the region of interest with the first image signals.
